(19) United States
(12) Patent Application Publication
(10) Pub. No.: US 2017/0256696 A1
(43) Pub. Date: Sep. 7, 2017

(54) THERMOELECTRIC GENERATOR

(71) Applicant: Taiwan Semiconductor Manufacturing Co., Ltd., Hsinchu (TW)

(72) Inventors: Jean-Pierre COLINGE, Hsinchu City (TW); Yu-Ming LIN, Taipei City (TW)

(73) Assignee: Taiwan Semiconductor Manufacturing Co., Ltd., Hsinchu (TW)

(21) Appl. No.: 15/057,734

(22) Filed: Mar. 1, 2016

(51) Int. Cl. H01L 35/32

(52) U.S. Cl. CPC H01L 35/325

(57) ABSTRACT

Thermoelectric generators are provided. A thermoelectric generator includes a thermoelectric structure and a rectifier bridge. The thermoelectric structure includes a semiconductor substrate, a first metal layer disposed on the semiconductor substrate, a dielectric layer disposed on the first metal layer, a second metal layer disposed on the dielectric layer, and a plurality of first materials disposed in the dielectric layer and coupled between the first electrodes and the second electrodes. The first metal layer includes a plurality of first electrodes. The second metal layer includes a plurality of second electrodes. The rectifier bridge coupled to the thermoelectric structure provides an output voltage according to electrical energy from the thermoelectric structure. The thermoelectric structure provides the electrical energy according to a temperature difference between the first metal layer and the second metal layer. The first material is a thermoelectric material.

### BACKGROUND

Energy harvesting technologies for converting ambient sparse energy to power, are used for the power supply of electronic devices.

Recently, an ultra-low-power (ULP) circuit for use in an Internet of Things (IoT) application is required to be self-generating. Furthermore, it is necessary for the ULP circuits to be so small, for example, that the size is on the scale of millimeters or smaller.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A through FIG. 1H show cross sectional views of intermediate stages of manufacturing a thermoelectric structure of a thermoelectric generator, in accordance with some embodiments of the disclosure.

FIG. 2A through FIG. 2G show shapes of the first-type nanowires and/or the second-type nanowire of the thermoelectric structure, in accordance with some embodiments of the disclosure.

FIG. 3 shows a thermoelectric generator, in accordance with some embodiments of the disclosure.

FIG. 4 shows a rectifier bridge, in accordance with some embodiments of the disclosure.

FIG. 5 shows a thermoelectric generator, in accordance with some embodiments of the disclosure.

FIG. 6 shows a thermoelectric generator, in accordance with some embodiments of the disclosure.

FIG. 7 shows a thermoelectric generator, in accordance with some embodiments of the disclosure.

FIG. 8 shows a top view of a thermoelectric structure of a micro energy harvesting device, in accordance with some embodiments of the disclosure.

FIG. 9 shows a top view of the thermoelectric structures of a micro energy harvesting device, in accordance with some embodiments of the disclosure.

FIG. 10 shows a top view of the thermoelectric structures of a micro energy harvesting device, in accordance with some embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In some embodiments, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Thermoelectric power generator is capable of converting a temperature difference of a material into electricity, specifically an electric signal. Such conversion is referred to as the Seebeck effect. For example, a temperature difference in a material causes free charge carriers in the material to diffuse from a hot side of the material to a cold side of the material, thereby giving rise to a thermoelectric voltage.

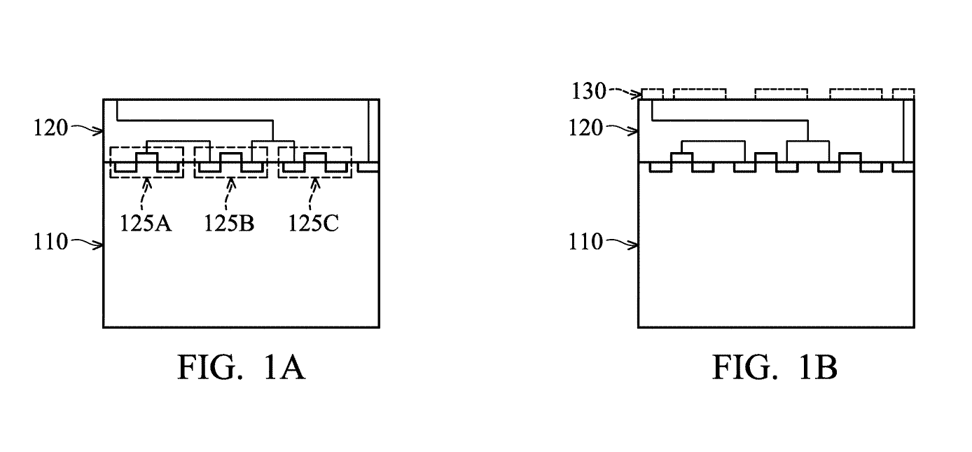

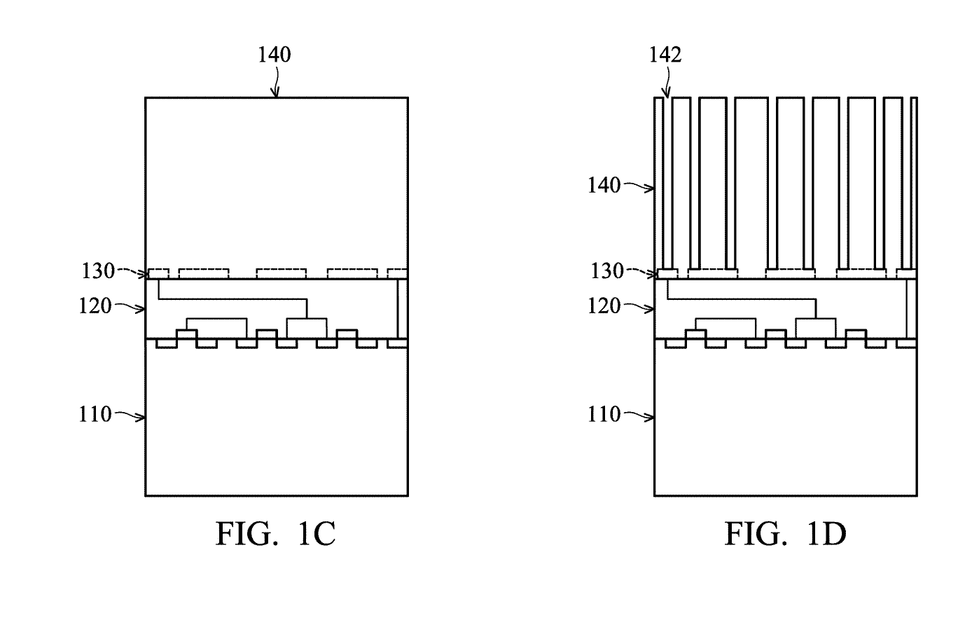

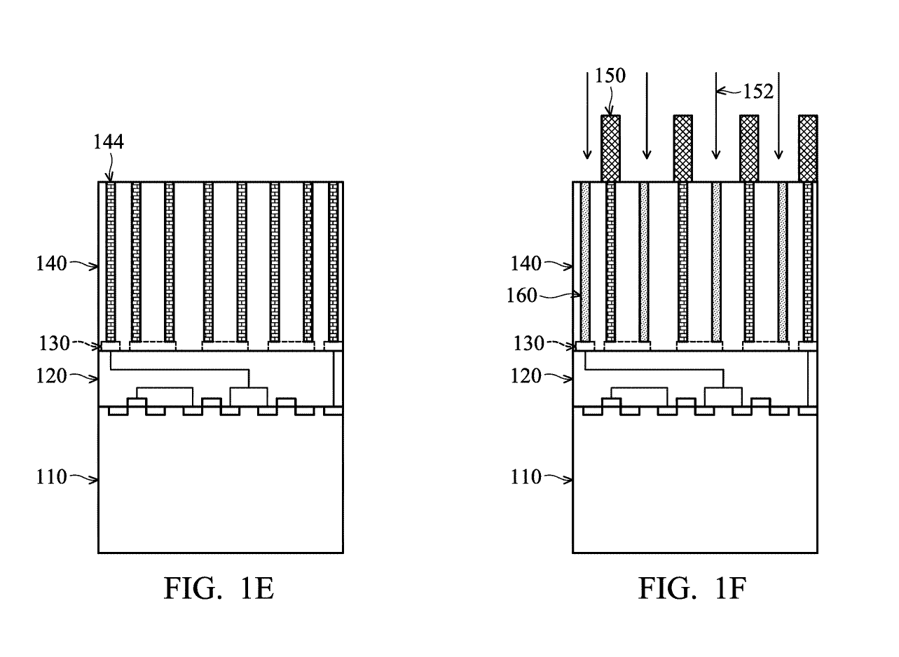

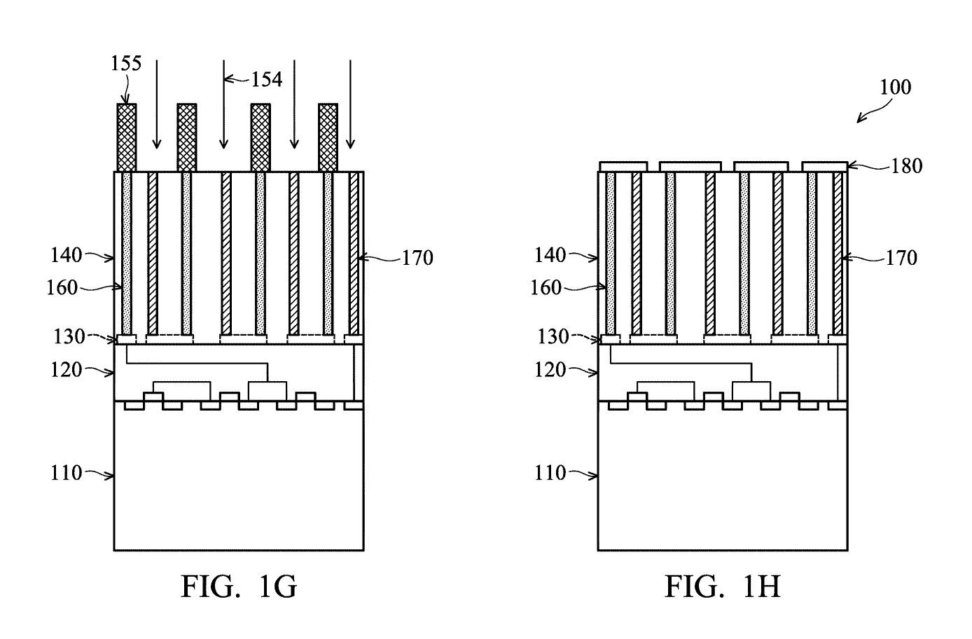

FIG. 1A through FIG. 1H show cross sectional views of intermediate stages of manufacturing a thermoelectric structure 100 of a thermoelectric generator, in accordance with some embodiments of the disclosure.

FIG. 1A shows a semiconductor substrate 110, a first dielectric layer 120 on the semiconductor substrate 110, and the devices 125A through 125C. In some embodiments, the semiconductor substrate 110 can be a bulk semiconductor substrate, a semiconductor-on-insulator (SOI) substrate, multi-layered or gradient substrate, or the like. The semiconductor of the semiconductor substrate 110 may include an elemental semiconductor, such as silicon, germanium, or the like. Furthermore, the semiconductor substrate 110 may further be a wafer, and the thermoelectric structure 110 is implemented in the thermoelectric generator of the wafer. In some embodiments, the first dielectric layer 120 is an inter-layer dielectric (ILD) layer that may include metal interconnections

A circuitry of the thermoelectric generator includes devices 125A through 125C. In some embodiments, the devices 125A through 125C are transistors in the circuitry, and drain/source regions of the transistors are disposed in the semiconductor substrate 110, and gate regions of the transistors are disposed in the first dielectric layer 120. In other embodiments, the devices 125A through 125C may be other active devices or passive devices in the circuitry.

In FIG. 1B, a deposition process and an etching process are performed to form the first electrodes 130 in a first metal layer on the first dielectric layer 120. In some embodiments, the first metal layer is a bottom metal layer.

In FIG. 1C, a deposition process is performed to form a second dielectric layer 140 on the first dielectric layer 120. Furthermore, the second dielectric layer 140 covers the first electrodes 130. In some embodiments, the second dielectric layer 140 is an inter-layer dielectric (ILD).

In FIG. 1D, an etching process is performed to form the holes 142 in the second dielectric layer 140. The top surfaces of the first electrodes 130 are exposed through the holes 142. The arrangement between the holes 142 and the first electrodes 130 will be illustrated in more detail below.

In FIG. 1E, an electroplating process or a deposition process (e.g. Chemical Vapor Deposition (CVD) or Atomic Layer Deposition (ALD)) is performed to deposit/grow a polycrystalline material 144 in the holes 142. In some embodiments, the polycrystalline material 144 is a thermoelectric material including Bismuth, Bi2Te3, Bi2Se3 or PbTe.

In FIG. 1F, a mask 150 formed by a resist material is disposed on the second dielectric layer 140. The mask 150 has a specific pattern, so as to cover a first portion of the polycrystalline material 144. An implant process is performed to implant a first-type material (as shown in label 152) into a second portion of the polycrystalline material 144, and the second portion of the polycrystalline material 144 is not covered by the mask 150. Thus, the nanowires 160 with a first-type dopant are formed. After completing the implant process, the mask 150 is stripped.

In FIG. 1G, a mask 155 formed by a resist material is disposed on the second dielectric layer 140. The mask 155 has a specific pattern, so as to cover the second portion of the polycrystalline material 144. An implant process is performed to implant a second-type material (as shown in label 154) into the first portion of the polycrystalline material 144, and the first portion of the polycrystalline material 144 is not covered by the mask 155. Thus, the nanowires 170 with a second-type dopant are formed. After completing the implant process, the mask 155 is stripped.

In some embodiments, the first-type material is an N-type material including Tellurium, and the second material is a P-type material including Tin, Boron or Gallium. In other embodiments, the first material is a P-type material including Tin, Boron or Gallium, and the second-type material is an N-type material including Tellurium.

In FIG. 1H, a deposition process and an etching process are performed to form the second electrodes 180 in a second metal layer on the second dielectric layer 140. Thus, the thermoelectric structure 100 is formed. In some embodiments, the second metal layer is a top metal layer. Furthermore, the first electrodes 130 form the bottom contacts for the nanowires 160 and 170, and the second electrodes 180 form the top contacts for the nanowires 160 and 170.

In some embodiments, an anneal process is performed on the thermoelectric structure 100 according to a specific temperature, such as above Bismuth melting temperature (272° C.), so as to recrystallize the polycrystalline material 144 of the nanowires 160 and 170.

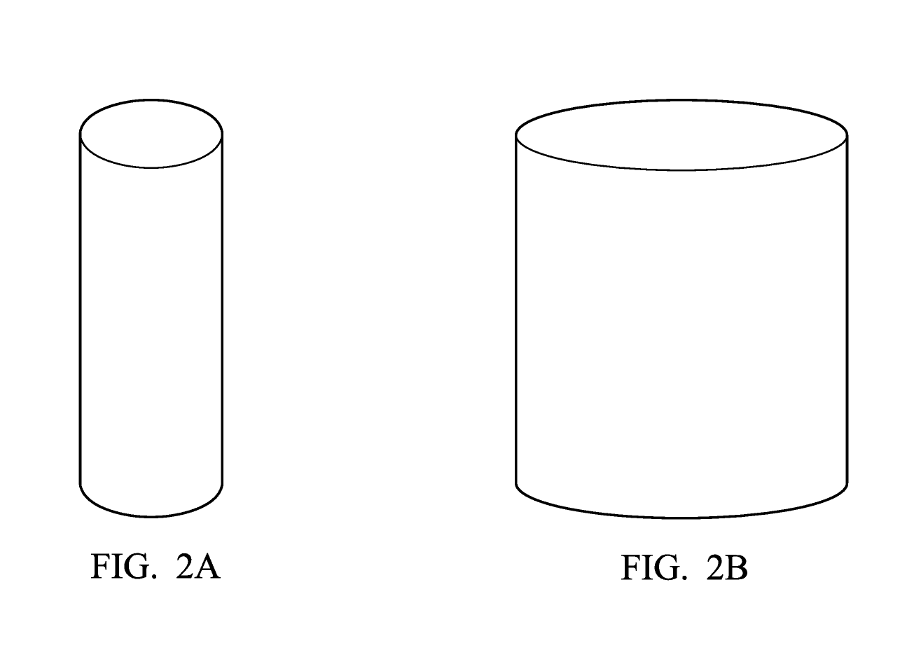

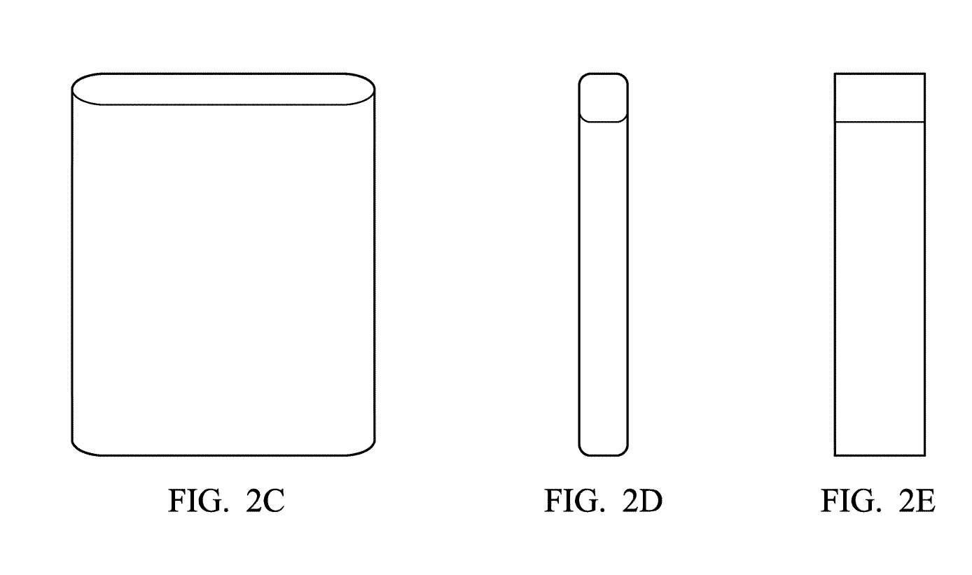

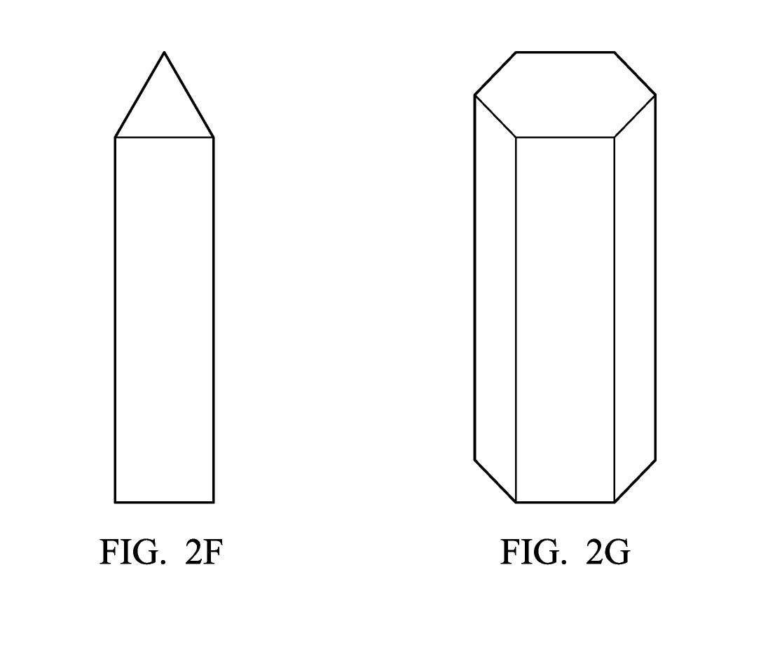

FIG. 2A through FIG. 2G show shapes of the first-type nanowires 160 and/or the second-type nanowire 170 of the thermoelectric structure 100 of FIG. 1H, in accordance with some embodiments of the disclosure.

In FIG. 2A, the nanowire 160/170 is a vertical wire having a circular cross section.

In FIG. 2B, the nanowire 160/170 is a vertical wire having an elliptical cross section.

In FIG. 2C, the nanowire 160/170 is a vertical wire having a rounded-corner rectangular cross section.

In FIG. 2D, the nanowire 160/170 is a vertical wire having a rounded-corner square cross section.

In FIG. 2E, the nanowire 160/170 is a vertical wire having a square or rectangular cross section.

In FIG. 2F, the nanowire 160/170 is a vertical wire having a triangular cross section.

In FIG. 2G, the nanowire 160/170 is a vertical wire having a hexagonal cross section.

The nanowire 160/170 can have other cross sections. The cross sections can be formed by the formation of the holes 142 of FIG. 1D, as one of ordinary skill in the art will readily understand. In some embodiments, the nanowire 160/17 can be a horizontal wire having a specific cross section, such as circular, elliptical, rounded-corner rectangular, rounded-corner square, square, rectangular, triangular, or hexagonal.

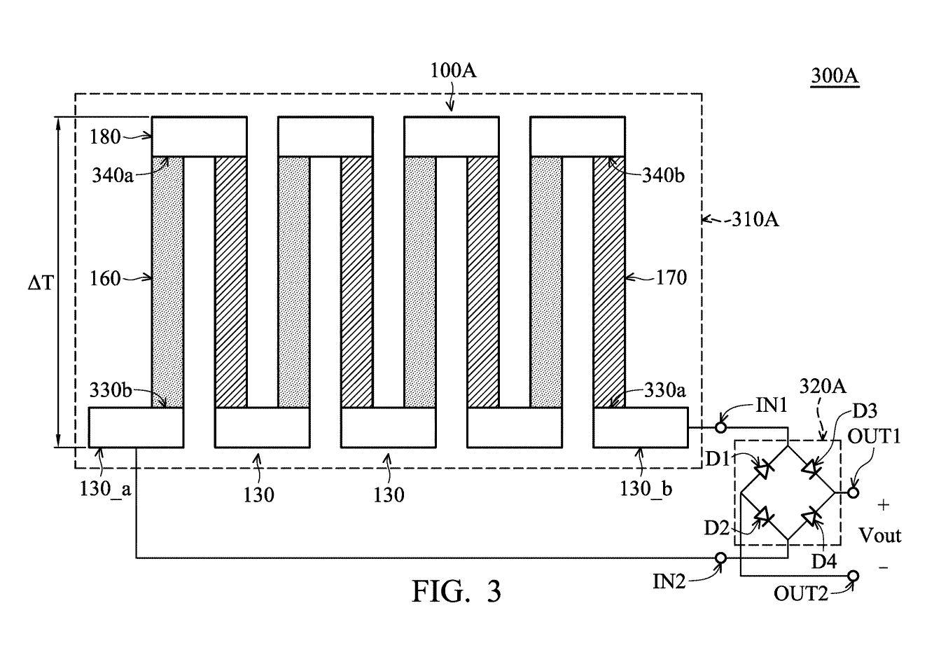

FIG. 3 shows a thermoelectric generator 300A, in accordance with some embodiments of the disclosure. The thermoelectric generator 300A includes a micro energy harvesting device 310A and a rectifier bridge 320A.

The micro energy harvesting device 310A includes a thermoelectric structure 100A. As described above, the thermoelectric structure 100A includes the first electrodes 130, the second electrodes 180, the first-type nanowires 160 and the second-type nanowires 170. In order to simplify the description, the other formations in the thermoelectric structure 100A will not be described further.

In some embodiments, the first-type nanowire 160 is a thermoelectric material doped with an N-type dopant, and the second-type nanowire 170 is a thermoelectric material doped with a P-type dopant. In other embodiments, the first-type nanowire 160 is a thermoelectric material doped with a P-type dopant, and the second-type nanowire 170 is a thermoelectric material doped with an N-type dopant.

The first-type nanowires 160 and the second-type nanowires 170 are coupled between the corresponding first electrodes 130 and the corresponding second electrodes 180. In FIG. 3, the first-type nanowire 160 is coupled between a terminal 340a of the second electrode 180 and a terminal 330b of the first electrode 130, and the second-type nanowire 170 is coupled between a terminal 340b of the second electrode 180 and a terminal 330a of the first electrode 130.

Accordingly, during operation, a hot side of the thermoelectric structure 100A drives electrons in the nanowires toward a cool side of the thermoelectric structure 100A, and a current I is generated. Holes in the nanowires will flow from the hot side to the cool side in the direction of the current I, thereby converting thermal energy into electrical energy.

The rectifier bridge 320A has a pair of input terminals IN1 and IN2 for receiving the electrical energy corresponding to the current I from the thermoelectric structure 100A. Furthermore, the rectifier bridge 320A has a pair of output terminals OUT1 and OUT2 for providing an output voltage Vout. According to the electrical energy corresponding to the current I from the thermoelectric structure 100A, the rectifier bridge 320A can provide the output voltage Vout at the output terminals OUT1 and OUT2.

It should be noted that the first-type nanowires 160, the second-type nanowires 170, the first electrodes 130, and the second electrodes 180 can be repeated numerous times to form an array, and the rectifier bridge 320A is coupled to the electrodes at ends of the array. For example, the input terminal IN1 of the rectifier bridge 320A is coupled to the first electrode 130_b, and the input terminal IN2 of the rectifier bridge 320A is coupled to the first electrode 130_a.

In some embodiments, the rectifier bridge 320A includes at least four diodes D1, D2, D3 and D4. The diode D1 has an anode coupled to the output terminal OUT2, and a cathode coupled to the input terminal IN1. The diode D2 has an anode coupled to the output terminal OUT2 and a cathode coupled to the input terminal IN2. The diode D3 has an anode coupled to the input terminal IN1 and a cathode coupled to the output terminal OUT1. The diode D4 has an anode coupled to the input terminal IN2 and a cathode coupled to the output terminal OUT1.

In FIG. 3, the first-type nanowire 160 and the second-type nanowire 170 coupled to the same second electrode 180 can be referred to as a pair of thermoelectric wires. The pairs of thermoelectric wires are arranged so that the thermoelectric structure 100A has alternating the first-type nanowires 160 and the second-type nanowires 170 electrically in series and thermally in parallel. For example, assuming that each pair of thermoelectric wires can generate about 1μ V/K. Thus, 1,000,000 pairs of thermoelectric wires can provide about 1V for Δ T=1K, where Δ T is a temperature difference between the first electrodes 130 and the second electrodes 180.

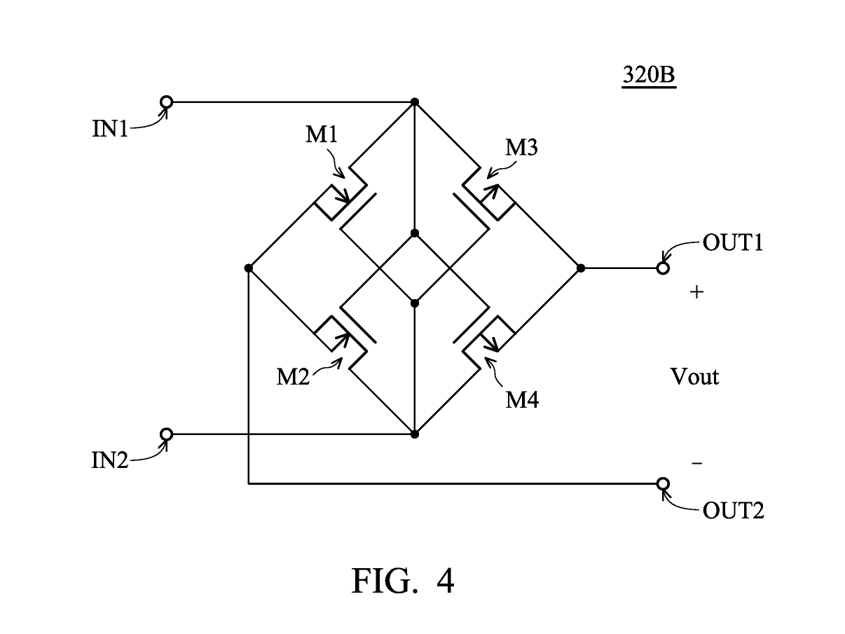

FIG. 4 shows a rectifier bridge 320B, in accordance with some embodiments of the disclosure. The rectifier bridge 320B has a pair of input terminals IN1 and IN2 and a pair of output terminals OUT1 and OUT2. The rectifier bridge 320B includes at least four transistors M1 through M4. The transistor M1 is an NMOS transistor coupled between the input terminal IN1 and the output terminal OUT2, and the transistor M1 has a gate coupled to the input terminal IN2. The transistor M2 is an NMOS transistor coupled between the input terminal IN2 and the output terminal OUT2, and the transistor M2 has a gate coupled to the input terminal IN1. In some embodiments, the bulks of the transistors M1 and M2 are coupled to the output terminal OUT2.

In the rectifier bridge 320B, the transistor M3 is a PMOS transistor coupled between the input terminal IN1 and the output terminal OUT1, and the transistor M3 has a gate coupled to the input terminal IN2. The transistor M4 is a PMOS transistor coupled between the input terminal IN2 and the output terminal OUT1, and the transistor M4 has a gate coupled to the input terminal IN1. In some embodiments, the bulks of the transistors M3 and M4 are coupled to the output terminal OUT1.

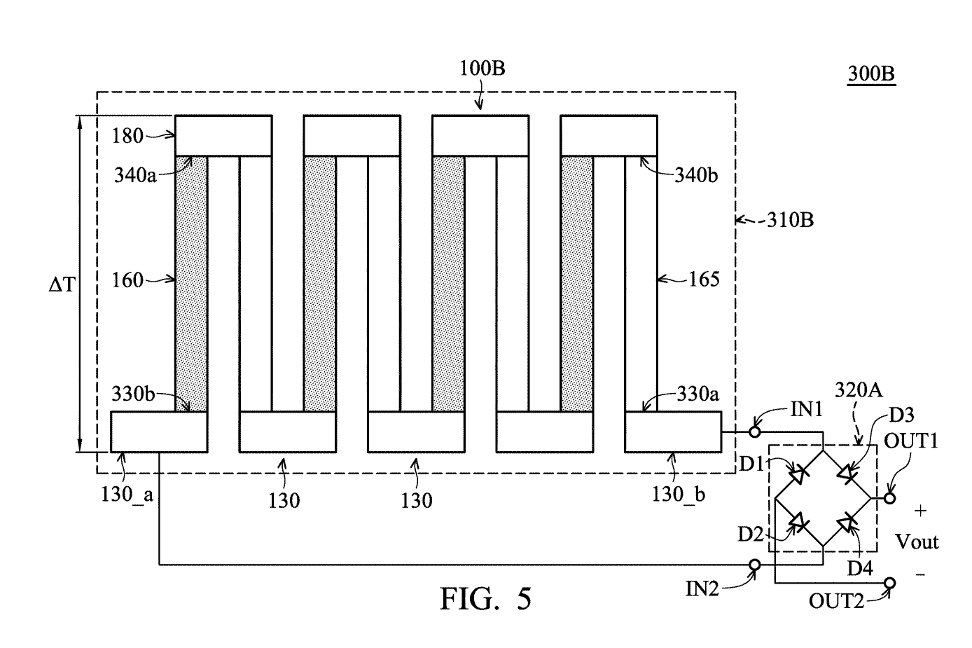

FIG. 5 shows a thermoelectric generator 300B, in accordance with some embodiments of the disclosure. The thermoelectric generator 300B includes a micro energy harvesting device 310B and a rectifier bridge 320A.

The micro energy harvesting device 310B includes a thermoelectric structure 100B. The thermoelectric structure 100B includes the first electrodes 130, the second electrodes 180, the first-type nanowires 160 and the third type nanowires 165. In order to simplify the description, the formations of the thermoelectric structure 310B similar to the formations of the thermoelectric structure 310A of FIG. 3 will not be described further.

In some embodiments, the first-type nanowire 160 is a thermoelectric material doped with an N-type dopant. In other embodiments, the first-type nanowire 160 is a thermoelectric material doped with a P-type dopant. It should be noted that the third type nanowire 165 is not a thermoelectric material. The third type nanowire 165 includes a conductivity material without a dopant. In some embodiments, the third type nanowires 165, the first electrodes 130 and the second electrodes 180 are formed of the same metal material.

In FIG. 5, the first-type nanowire 160 is coupled between a terminal 340a of the second electrode 180 and a terminal 330b of the first electrode 130, and the third type nanowires 165 is coupled between a terminal 340b of the second electrode 180 and a terminal 330a of the first electrode 130.

In the embodiment, the first-type nanowire 160 and the third type nanowire 165 coupled to the same second electrode 180 can be referred to as a pair of conductivity wires. The pairs of conductivity wires are arranged so that the thermoelectric structure 100B has alternating the first-type nanowires 160 and the third type nanowires 165 electrically in series and thermally in parallel. For example, assuming that the first-type nanowire 160 is a thermoelectric material doped with an N-type dopant and each pair of conductivity wires can generate about 0.7μ V/K. Thus, 1,000,000 pairs of thermoelectric wires can provide about 1.4V for Δ T=2K, where Δ T is a temperature difference between the first electrodes 130 and the second electrodes 180. Furthermore, assuming that the first-type nanowire 160 is a thermoelectric material doped with a P-type dopant and each pair of conductivity wires can generate about 0.35μ V/K. Thus, 1,000,000 pairs of thermoelectric wires can provide about 0.7V for Δ T=2K.

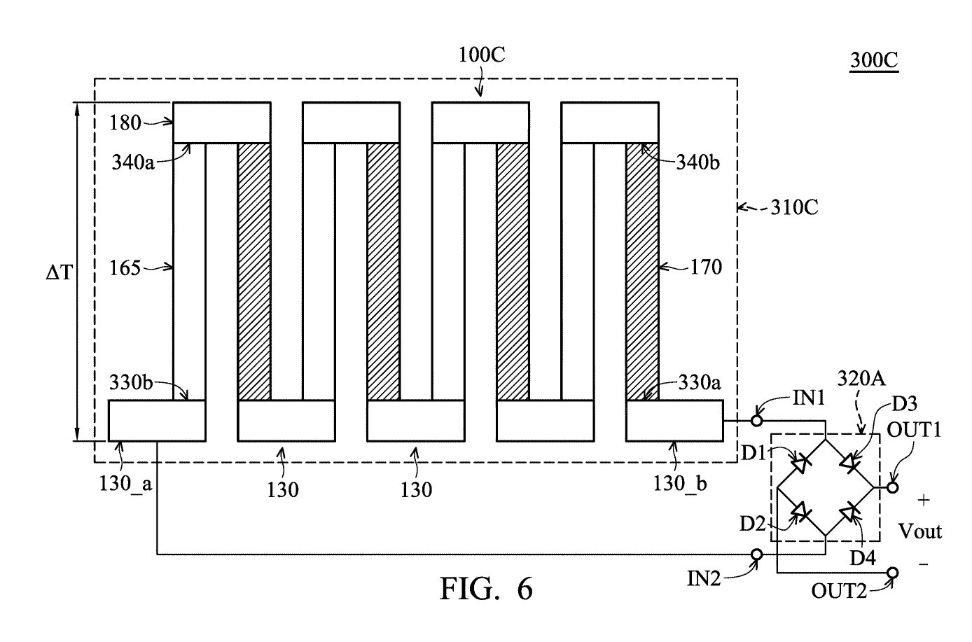

FIG. 6 shows a thermoelectric generator 300C, in accordance with some embodiments of the disclosure. The thermoelectric generator 300C includes a micro energy harvesting device 310C and a rectifier bridge 320A.

The micro energy harvesting device 310C includes a thermoelectric structure 100C. The thermoelectric structure 100C includes the first electrodes 130, the second electrodes 180, the second-type nanowires 170 and the third type nanowires 165. In order to simplify the description, the formations of the thermoelectric structure 310C similar to the formations of the thermoelectric structure 310A of FIG. 3 will not be described further.

In some embodiments, the second-type nanowire 170 is a thermoelectric material doped with an N-type dopant. In other embodiments, the second-type nanowire 170 is a thermoelectric material doped with a P-type dopant. It should be noted that the third type nanowire 165 is not a thermoelectric material. The third type nanowire 165 includes a conductivity material without dopant. In some embodiments, the third type nanowires 165, the first electrodes 130 and the second electrodes 180 are formed of the same metal material.

In FIG. 6, the second-type nanowire 170 is coupled between a terminal 340b of the second electrode 180 and a terminal 330a of the first electrode 130, and the third type nanowires 165 is coupled between a terminal 340a of the second electrode 180 and a terminal 330b of the first electrode 130.

In the embodiment, the second-type nanowire 170 and the third type nanowire 165 coupled to the same second electrode 180 can be referred to as a pair of conductivity wires. The pairs of conductivity wires are arranged so that the thermoelectric structure 100C has alternating the second-type nanowires 170 and the third type nanowires 165 electrically in series and thermally in parallel. For example, assuming that the second-type nanowire 170 is a thermoelectric material doped with an N-type dopant and each pair of conductivity wires can generate about 0.7μ V/K. Thus, 1,000,000 pairs of thermoelectric wires can provide about 1.4V for Δ T=2K, where Δ T is a temperature difference between the first electrodes 130 and the second electrodes 180. Furthermore, assuming that the second-type nanowire 170 is a thermoelectric material doped with a P-type dopant and each pair of conductivity wires can generate about 0.35μ V/K. Thus, 10,00,000 pairs of thermoelectric wires can provide about 0.7V for Δ T=2K.

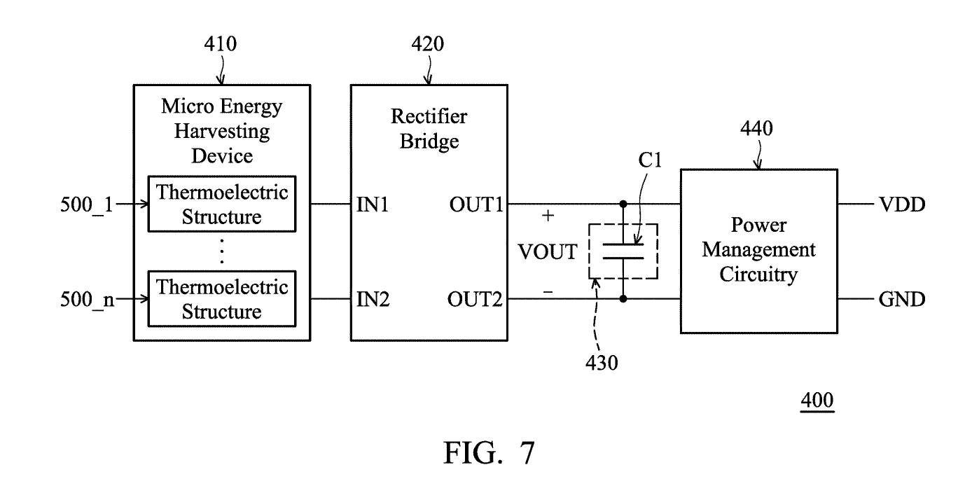

FIG. 7 shows a thermoelectric generator 400, in accordance with some embodiments of the disclosure. The thermoelectric generator 400 includes a micro energy harvesting device 410 and a rectifier bridge 420. Furthermore, the thermoelectric generator 400 further includes an energy storage device 430 and a power management circuitry 440.

The micro energy harvesting device 410 includes one or more thermoelectric structures 500_1 through 500_n. In some embodiments, parallel/series associations of the thermoelectric structures 500_1 through 500_n can increase the electrical energy produced by the thermoelectric generator 400. The parallel/series associations of the thermoelectric structures will be illustrated in more detail below.

As described above, the rectifier bridge 420 may include at least four diodes D1, D2, D3 and D4 (e.g. 320A of FIG. 3) or at least four transistors M1 through M4 (e.g. 320B of FIG. 4). Furthermore, the rectifier bridge 420 has a pair of input terminals IN1 and IN2 for receiving the electrical energy corresponding to the current I from the thermoelectric structure 410, and a pair of output terminals OUT1 and OUT2 for providing an output voltage Vout.

The energy storage device 430 is coupled to the output terminals OUT1 and OUT2 of the rectifier bridge 420, and the energy storage device 430 is capable of storing the output voltage Vout from the rectifier bridge 420. In some embodiments, the energy storage device 430 includes a capacitor or a super-capacitor C1. In other embodiments, the energy storage device 430 includes a rechargeable battery.

The power management circuitry 440 is coupled to the energy storage device 430. The power management circuitry 440 is capable of modifying the output voltage Vout stored in the energy storage device 430 to provide a voltage VDD. In some embodiments, the power management circuitry 440 is a voltage converter, or a charge pumping circuitry.

The voltage VDD provided by the power management circuitry 440 can be used as a supply voltage (or a power supply) of an electric device, such as a wearable device, a portable device, a mobile device or an ultra-low-power (ULP) circuit used in an Internet of Things (IoT) application. It should be noted that the thermoelectric generator 400 is implemented in the electric device for powering the electric device. Furthermore, the power management circuitry 440 is capable of controlling an operation mode (e.g. a sleep mode or an active mode) of the electric device, so as to control power consumption of the electric device.

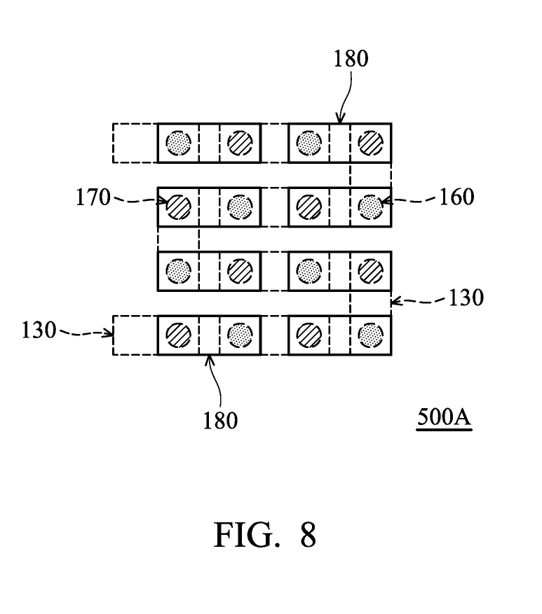

FIG. 8 shows a top view of a thermoelectric structure 500A of a micro energy harvesting device, in accordance with some embodiments of the disclosure. The thermoelectric structure 500A includes the second electrodes 180, the first electrodes 130, the first-type nanowires 160, and the second-type nanowires 170. As described above, the second electrodes 180 can be formed in a top metal layer of a chip, and the first electrodes 130 can be formed in a lower metal layer of the chip. In order to simplify the description, the formations below the first electrodes 130 in the thermoelectric structure 500A will not be described further.

The first-type nanowires 160 and the second-type nanowires 170 are coupled between the second electrodes 180 and the first electrodes 130. The first-type nanowire 160 and the second-type nanowire 170 coupled to the same second electrodes 180 can be referred to as a pair of thermoelectric wires. For the pair of thermoelectric wires, the first-type nanowire 160 and the second-type nanowire 170 are respectively coupled to two different first electrodes 130, and the two first electrodes 130 are adjacent to each other.

It should be noted that 8 pairs of thermoelectric wires shown in the thermoelectric structure 500A is used as an example. The number of pairs of thermoelectric wires in a thermoelectric structure is determined according to various applications.

The first-type nanowires 160, the second-type nanowires 170, the second electrodes 180, and the first electrodes 130 can be repeated numerous times to form an array. A rectifier bridge of the thermoelectric generator is coupled to the first electrodes 130 at ends of the array.

In some embodiments, the first-type nanowire 160 is a thermoelectric material doped with an N-type dopant, and the second-type nanowire 170 is a thermoelectric material doped with a P-type dopant or the second-type nanowire 170 may be replaced with the third type nanowire 165, i.e. a conductivity material without a dopant. In other embodiments, the first-type nanowire 160 is a thermoelectric material doped with a P-type dopant, and the second-type nanowire 170 is a thermoelectric material doped with an N-type dopant or the second-type nanowire 170 may be replaced with the third type nanowire 165.

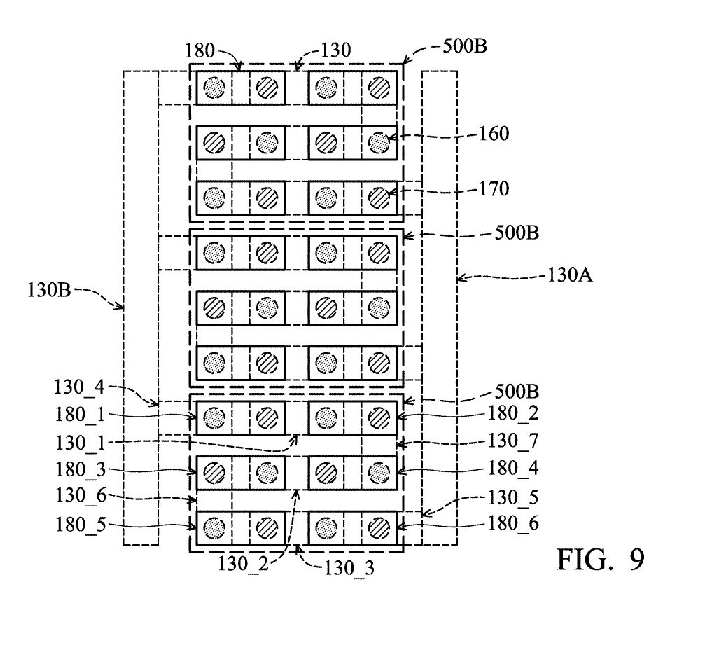

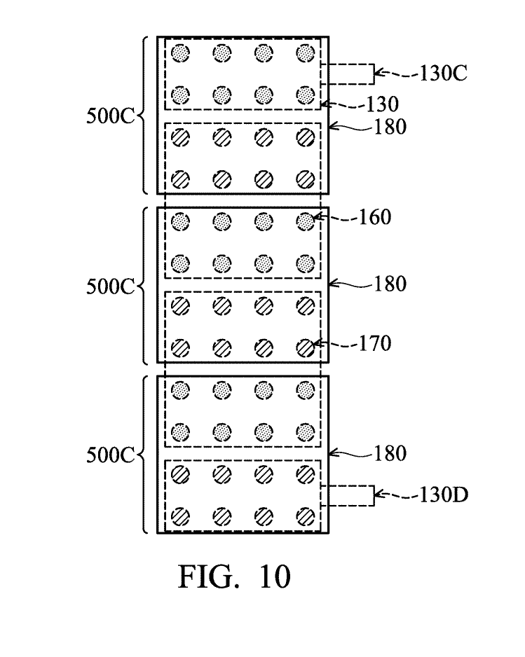

FIG. 9 shows a top view of the thermoelectric structures 500B of a micro energy harvesting device, in accordance with some embodiments of the disclosure. In some embodiments, the thermoelectric structures 500B have the same layout and structure. In FIG. 9, each thermoelectric structure includes the second electrodes 180, the first electrodes 130, the first-type nanowires 160, and the second-type nanowires 170. As described above, the second electrodes 180 can be formed in a top metal layer of a chip, and the first electrodes 130 can be formed in a lower metal layer of the chip. In order to simplify the description, the formations below the first electrodes 130 in the thermoelectric structures 500B will not be described further.

Taking the thermoelectric structure 500B as an example for the purposes of illustration, the second electrodes 180_1 through 180_6 are arranged in parallel in a first direction. The first electrodes 130_1 through 130_5 are arranged in parallel in the first direction, and the first electrodes 130_6 through 130_7 are arranged in parallel in a second direction different from the first direction. In some embodiments, the second direction (e.g. a vertical line) is perpendicular to the first direction (e.g. a horizontal line). In the embodiment, the first electrode 130_6 is disposed on the left side of the first electrodes 130_1 through 130_3, and the first electrode 130_7 is disposed on the right side of the first electrodes 130_1 through 130_3. In some embodiments, the first electrodes 130_6 and 130_7 are used to couple the bottom electrodes disposed in different rows.

In some embodiments, the first-type nanowire 160 is a thermoelectric material doped with an N-type dopant, and the second-type nanowire 170 is a thermoelectric material doped with a P-type dopant or the second-type nanowire 170 may be replaced with the third type nanowire 165, i.e. a conductivity material without a dopant. In other embodiments, the first-type nanowire 160 is a thermoelectric material doped with a P-type dopant, and the second-type nanowire 170 is a thermoelectric material doped with an N-type dopant or the second-type nanowire 170 may be replaced with the third type nanowire 165.

The first-type nanowire 160 and the second-type nanowire 170 coupled to the same second electrode 180 can be referred to as a pair of thermoelectric wires. For the pair of thermoelectric wires, the first-type nanowire 160 and the second-type nanowire 170 are respectively coupled to two different first electrodes 130, and the two first electrodes 130 are adjacent to each other.

For example, in the thermoelectric structure 500B, the second electrode 180_1 is coupled to the first electrode 130_4 via the first-type nanowire 160, and the second electrode 180_1 is coupled to the first electrode 130_1 via the second-type nanowire 170. The second electrode 180_2 is coupled to the first electrode 130_1 via the first-type nanowire 160, and the second electrode 180_2 is coupled to the first electrode 130_7 via the second-type nanowire 170. The second electrode 180_4 is coupled to the first electrode 130_7 via the first-type nanowire 160, and the second electrode 180_4 is coupled to the first electrode 130_2 via the second-type nanowire 170. The second electrode 180_3 is coupled to the first electrode 130_2 via the first-type nanowire 160, and the second electrode 180_3 is coupled to the first electrode 130_6 via the second-type nanowire 170. The first electrode 180_5 is coupled to the second electrode 130_6 via the first-type nanowire 160, and the first electrode 180_5 is coupled to the second electrode 130_3 via the second-type nanowire 170. The first electrode 180_6 is coupled to the second electrode 130_3 via the first-type nanowire 160, and the second electrode 180_6 is coupled to the first electrode 130_5 via the second-type nanowire 170.

In the thermoelectric structures 500B, 6 pairs of thermoelectric wires coupled in series is used as an example. The number of pairs of thermoelectric wires coupled in series in a thermoelectric structure is determined according to various applications.

In FIG. 9, the thermoelectric structures 500B are coupled in parallel via the first electrodes 130A and 130B. For example, the first electrodes 130_4 of the thermoelectric structures 500B are coupled to the first electrode 130B, and the first electrodes 130_5 of the thermoelectric structures 500B are coupled to the first electrode 130A.

In some embodiments, the first electrodes 130A and 130B can directly connect to the first electrodes 130_4 and 130_5 of the thermoelectric structures 500B. In other embodiments, the first electrodes 130A and 130B may be replaced with the electrodes disposed in a metal layer except the lower metal layers. If the electrodes 130A and 130B are disposed in a specific metal layer except the lower metal layer, the electrodes 130A and 130B are coupled to the first electrodes 130_4 and 130_5 of the thermoelectric structures 500B through the vias between the specific metal layer and the lower metal layer.

The thermoelectric structures 500B are coupled in parallel. Parallel associations of the thermoelectric structures 500B can increase a current produced by the thermoelectric generator. In each of thermoelectric structures 500B, during operation, a hot side of the thermoelectric structure will drives electrons in the nanowires toward a cool side of the thermoelectric structure, and a current I is generated for each thermoelectric structure. Specifically, when a temperature difference is present between the first electrodes 130 and the second electrodes 180 in each thermoelectric structure of FIG. 9, the current I flowing through the thermoelectric structure is generated between the first electrodes 130A and 130B.

In some embodiments, an input terminal IN1 of a rectifier bridge is coupled to the electrode 130A, and an input terminal IN2 of the rectifier bridge is coupled to the electrode 130B. Thus, the rectifier bridge can provide an output voltage Vout according to the electrical energy corresponding to the total current (i.e. 3I) from the thermoelectric structures 500B.

FIG. 10 shows a top view of the thermoelectric structures 500C of a micro energy harvesting device, in accordance with some embodiments of the disclosure. In some embodiments, the thermoelectric structures 500C have the same layout and structure. Each thermoelectric structures 500 includes the second electrodes 180, the first electrodes 130, the first-type nanowires 160, and the second-type nanowires 170. As described above, the second electrodes 180 can be formed in a top metal layer of a chip, and the first electrodes 130 can be formed in a lower metal layer of the chip. In order to simplify the description, the formations below the first electrodes 130 in the thermoelectric structures 500C will not be described further.

A single first-type nanowire 160 and a single second-type nanowire 170 coupled to the same second electrode 180 can be referred to as a pair of thermoelectric wires. In FIG. 10, there are 8 pairs of thermoelectric wires in the second electrode 180 of the thermoelectric structures of FIG. 10. It should be noted that 8 pairs of thermoelectric wires shown in the second electrode 180 is used as an example. The number of pairs of thermoelectric wires in a second electrode 180 is determined according to various applications. Parallel associations of the pairs of thermoelectric wires can increase a current produced by the thermoelectric structure.

For 8 pairs of thermoelectric wires, the first-type nanowires 160 and the second-type nanowires 170 are respectively coupled to two different first electrodes 130, and the two first electrodes 130 are adjacent to each other.

In some embodiments, the first-type nanowire 160 is a thermoelectric material doped with an N-type dopant, and the second-type nanowire 170 is a thermoelectric material doped with a P-type dopant or the second-type nanowire 170 may be replaced with the third type nanowire 165, i.e. a conductivity material without a dopant. In other embodiments, the first-type nanowire 160 is a thermoelectric material doped with a P-type dopant, and the second-type nanowire 170 is a thermoelectric material doped with an N-type dopant or the second-type nanowire 170 may be replaced with the third type nanowire 165.

In FIG. 10, the thermoelectric structures 500C are coupled in serial via the first electrodes 130. In some embodiments, the thermoelectric structures 500C can be coupled in serial via the electrodes disposed in the other metal layer.

In some embodiments, an input terminal IN1 of a rectifier bridge is coupled to the first thermoelectric structure 500C through the first electrode 130C, and an input terminal IN2 of the rectifier bridge is coupled to the third thermoelectric structure 500C through the first electrode 130D. When a temperature difference is present between the second electrodes 180 and the first electrodes 130 in the thermoelectric structures 500C, the current I flowing through the thermoelectric structures 500C is generated between the first electrodes 130C and 130D. Thus, the rectifier bridge can provide an output voltage Vout according to the electrical energy corresponding to the current from the thermoelectric structures 500C.

Embodiments for fabricating integrated thermoelectric generators are provided. The thermoelectric generator includes a micro energy harvesting device and a rectifier bridge in a chip. The micro energy harvesting device includes one or more thermoelectric structures capable of producing electrical energy from a temperature difference between the top (e.g. the front) and the bottom (e.g. the back) of the chip. The temperature gradient between the top and the bottom of the chip can be either positive or negative. The electrical energy is the source of energy for ULP circuits used in IoT applications. For example, if a wearable device includes a thermoelectric generator with a rectifier bridge, the rectifier bridge can convert a temperature difference between a human body and its surroundings into electrical energy, so as to power the wearable device. Energy harvesting is forecast to be widely used in IoT. The chips of IoT will use very low power and will not need an on-board energy source. By integrating a Seebeck thermoelectric generator on a silicon chip, harvesting energy from small thermal gradients is provided instead of the typical energy sources, such as photoelectric (mini solar cells) and triboelectric (using movement or friction).

In some embodiments, a thermoelectric generator is provided. The thermoelectric generator includes a thermoelectric structure and a rectifier bridge coupled to the thermoelectric structure. The thermoelectric structure includes a semiconductor substrate, a first metal layer disposed on the semiconductor substrate, a dielectric layer disposed on the first metal layer, a second metal layer disposed on the dielectric layer, and a plurality of first materials disposed in the dielectric layer and coupled between the first electrodes and the second electrodes. The first metal layer includes a plurality of first electrodes. The second metal layer includes a plurality of second electrodes. The rectifier bridge coupled to the thermoelectric structure provides an output voltage according to electrical energy from the thermoelectric structure. The thermoelectric structure provides the electrical energy according to a temperature difference between the first metal layer and the second metal layer. The first material is a thermoelectric material.

In some embodiments, another thermoelectric generator is provided. The thermoelectric generator includes a plurality of thermoelectric structures. Each of the thermoelectric structures includes a semiconductor substrate, a first metal layer disposed on the semiconductor substrate, a dielectric layer disposed on the first metal layer, a second metal layer disposed on the dielectric layer, a plurality of first materials disposed in the dielectric layer, and a plurality of second materials disposed in the dielectric layer. The first metal layer includes a plurality of first electrodes arranged in parallel in a first direction, and a plurality of second electrodes arranged in parallel in a second direction perpendicular to the first direction. The second metal layer includes a plurality of third electrodes arranged in parallel in the first direction. Each of the first materials is coupled between a first terminal of the individual first or second electrode and a first terminal of the individual third electrode. Each of the second material is coupled between a second terminal of the individual first or second electrode and a second terminal of the individual third electrode. The first material or the second material a thermoelectric material. Each of the thermoelectric structures provides electrical energy according to a temperature difference between the first metal layer and the second metal layer in the thermoelectric structure.

In some embodiments, another thermoelectric generator is provided. The thermoelectric generator includes a plurality of thermoelectric structures. Each of thermoelectric structures includes a semiconductor substrate, a first metal layer disposed on the semiconductor substrate, a dielectric layer disposed on the first metal layer, a second metal layer disposed on the dielectric layer, a plurality of first materials disposed in the dielectric layer, and a plurality of second materials disposed in the dielectric layer. The first metal layer includes a first electrode and a second electrode. The second metal layer includes a third electrode. The first materials are coupled between the first electrode and the third electrode in parallel. The second materials are coupled between the second electrode and the third electrode in parallel. The thermoelectric generator further includes a fourth electrode coupled to the first electrode of a first thermoelectric structure of the thermoelectric structures, and a fifth electrode coupled to the second electrode of a second thermoelectric structure of the thermoelectric structures. The first material or the second material a thermoelectric material. Each of the thermoelectric structures provides electrical energy according to a temperature difference between the first metal layer and the second metal layer in the thermoelectric structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A thermoelectric generator, comprising:
a thermoelectric structure, comprising:
a semiconductor substrate;
a first metal layer disposed on the semiconductor substrate, comprising a plurality of first electrodes;
a dielectric layer disposed on the first metal layer;
a second metal layer disposed on the dielectric layer, comprising a plurality of second electrodes; and
a plurality of first materials disposed in the dielectric layer and coupled between the first electrodes and the second electrodes; and
a rectifier bridge coupled to the thermoelectric structure, providing an output voltage according to electrical energy from the thermoelectric structure,
wherein the thermoelectric structure provides the electrical energy according to a temperature difference between the first metal layer and the second metal layer,
wherein the first material is a thermoelectric material.

2. The thermoelectric generator as claimed in claim 1, wherein the rectifier bridge has a first input terminal coupled to a first specific electrode of the first electrodes, a second input terminal coupled to a second specific electrode of the first electrodes, a first output terminal and a second output terminal, and comprises:
a first diode, having a cathode coupled to the first input terminal, and an anode coupled to the second output terminal;
a second diode, having a cathode coupled to the second input terminal, and an anode coupled to the second output terminal;
a third diode, having a cathode coupled to the first output terminal, and an anode coupled to the first input terminal; and
a fourth diode, having a cathode coupled to the first output terminal, and an anode coupled to the second input terminal,
wherein the rectifier bridge provides the output voltage at the first and second output terminals.

3. The thermoelectric generator as claimed in claim 1, wherein the rectifier bridge has a first input terminal coupled to a first specific electrode of the first electrodes, a second input terminal coupled to a second specific electrode of the first electrodes, a first output terminal and a second output terminal, and comprises:
a first NMOS transistor coupled between the first input terminal and the second output terminal, having a gate coupled to the second input terminal, and a bulk coupled to the second output terminal;
a second NMOS transistor coupled between the second input terminal and the second output terminal, having a gate coupled to the first input terminal, and a bulk coupled to the second output terminal;
a first PMOS transistor coupled between the first output terminal and the first input terminal, having a gate coupled to the second input terminal, and a bulk coupled to the first output terminal; and
a second PMOS transistor coupled between the first output terminal and the second input terminal, having a gate coupled to the first input terminal, and a bulk coupled to the first output terminal,
wherein the rectifier bridge provides the output voltage at the first and second output terminals.

4. The thermoelectric generator as claimed in claim 1, further comprising:
an energy storage device coupled to the rectifier bridge, storing the output voltage; and
a power management circuitry coupled to the energy storage device, providing a supply voltage according to the stored output voltage.

5. The thermoelectric generator as claimed in claim 1, further comprising:
a plurality of second materials disposed in the dielectric layer and coupled between the first electrodes and the second electrodes,
wherein each of the first materials is coupled between a first terminal of the corresponding first electrode and a first terminal of the corresponding second electrode, and each of the second material is coupled between a second terminal of the corresponding first electrode and a second terminal of the corresponding second electrode.

6. The thermoelectric generator as claimed in claim 5, wherein when the first material is a thermoelectric material doped with an N-type dopant, the second material is a thermoelectric material doped with a P-type dopant, and when the first material is a thermoelectric material doped with a P-type dopant, the second material is a thermoelectric material doped with an N-type dopant.

7. The thermoelectric generator as claimed in claim 5, wherein when the first material is a thermoelectric material doped with an N-type dopant, the second materials is a conductivity material without a dopant.

8. The thermoelectric generator as claimed in claim 5, wherein when the first material is a thermoelectric material doped with a P-type dopant, the second materials is a conductivity material without a dopant.

9. The thermoelectric generator as claimed in claim 5, wherein the thermoelectric structure and the rectifier bridge are implemented in a chip, wherein the first metal layer is a lower metal layer of the chip, and the second metal layer is a top metal layer of the chip.

10. The thermoelectric generator as claimed in claim 1, wherein the first material is a thermoelectric material comprising Bismuth, Bi₂Te₃, Bi₂Se₃ or PbTe.

11. A thermoelectric generator, comprising:
a plurality of thermoelectric structures, each comprising:
a semiconductor substrate;
a first metal layer disposed on the semiconductor substrate, comprising a plurality of first electrodes arranged in parallel in a first direction, and a plurality of second electrodes arranged in parallel in a second direction perpendicular to the first direction;
a dielectric layer disposed on the first metal layer;
a second metal layer disposed on the dielectric layer, comprising a plurality of third electrodes arranged in parallel in the first direction;
a plurality of first materials disposed in the dielectric layer, wherein each of the first materials is coupled between a first terminal of the individual first or second electrode and a first terminal of the individual third electrode; and
a plurality of second materials disposed in the dielectric layer, wherein each of the second material is coupled between a second terminal of the individual first or second electrode and a second terminal of the individual third electrode,
wherein the first material or the second material a thermoelectric material,
wherein each of the thermoelectric structures provides electrical energy according to a temperature difference between the first metal layer and the second metal layer in the thermoelectric structure.

12. The thermoelectric generator as claimed in claim 11, further comprising:
a rectifier bridge coupled to the thermoelectric structures, providing an output voltage according to the electrical energy from the thermoelectric structures.

13. The thermoelectric generator as claimed in claim 11, further comprising:
a fourth electrode coupled to a first specific electrode of the first electrodes of each of the thermoelectric structures; and
a fifth electrode coupled to a second specific electrode of the first electrodes of each of the thermoelectric structures,
wherein the thermoelectric structures are coupled in parallel between the fourth electrode and the fifth electrode.

14. The thermoelectric generator as claimed in claim 13, further comprising:
a rectifier bridge coupled to the thermoelectric structures through the fourth and fifth electrodes, providing an output voltage according to the electrical energy from the thermoelectric structures through the fourth and fifth electrodes.

15. The thermoelectric generator as claimed in claim 11, wherein in each of the thermoelectric structures, when the first material is a thermoelectric material doped with an N-type dopant, the second material is a thermoelectric material doped with a P-type dopant, and when the first material is a thermoelectric material doped with a P-type dopant, the second material is a thermoelectric material doped with an N-type dopant.

16. The thermoelectric generator as claimed in claim 11, wherein one of the first and second materials is a thermoelectric material doped with an N-type dopant or a P-type dopant, and another of the first and second materials is a conductivity material without a dopant.

17. The thermoelectric generator as claimed in claim 11, wherein the first or second material is a thermoelectric material comprising Bismuth, Bi₂Te₃, Bi₂Se₃ or PbTe.

18. A thermoelectric generator, comprising:
a plurality of thermoelectric structures, each comprising:
a semiconductor substrate;
a first metal layer disposed on the semiconductor substrate, comprising a first electrode and a second electrode;
a dielectric layer disposed on the first metal layer;
a second metal layer disposed on the dielectric layer, comprising a third electrode;
a plurality of first materials disposed in the dielectric layer, wherein the first materials are coupled between the first electrode and the third electrode in parallel; and
a plurality of second materials disposed in the dielectric layer, wherein the second materials are coupled between the second electrode and the third electrode in parallel, and
a fourth electrode coupled to the first electrode of a first thermoelectric structure of the thermoelectric structures; and
a fifth electrode coupled to the second electrode of a second thermoelectric structure of the thermoelectric structures,
wherein the first material or the second material a thermoelectric material,
wherein each of the thermoelectric structures provides electrical energy according to a temperature difference between the first metal layer and the second metal layer in the thermoelectric structure.

19. The thermoelectric generator as claimed in claim 18, wherein the thermoelectric structures are coupled in series by connecting the first electrode of one of the thermoelectric structures to the second electrode of the thermoelectric structure adjacent to the one of the thermoelectric structures.

20. The thermoelectric generator as claimed in claim 18, further comprising:
a rectifier bridge coupled to the thermoelectric structures through the fourth electrode and the fifth electrode, providing an output voltage according to the electrical energy from the thermoelectric structures.
